(19) United States
(12) Patent Application Publication
(10) Pub. No.: US 2019/0378963 A1
(43) Pub. Date: Dec. 12, 2019

(54) ELECTRONIC APPARATUS AND METHOD FOR MANUFACTURING THE SAME

(71) Applicant: Advanced Semiconductor Engineering, Inc., Kaohsiung (TW)

(72) Inventors: Ming-Te LIU, Kaohsiung (TW); Chien Lin CHANG CHIEN, Kaohsiung (TW); Chang Chi LEE, Kaohsiung (TW)

(73) Assignee: Advanced Semiconductor Engineering, Inc., Kaohsiung (TW)

(21) Appl. No.: 16/430,226

(22) Filed: Jun. 3, 2019

Related U.S. Application Data
(60) Provisional application No. 62/681,533, filed on Jun. 6, 2018.

(51) Int. Cl. H01L 33/62; H01L 33/40; H01L 33/30; H01L 33/00; H01L 25/075; H01L 25/16

(52) U.S. Cl. CPC H01L 33/62; H01L 33/40; H01L 33/30; H01L 33/24; H01L 25/0753; H01L 25/167; H01L 33/0066

(57) ABSTRACT

An electronic apparatus includes a substrate structure, a plurality of pillar bases, at least one light emitting device and a plurality of electrically connective materials. The substrate structure has a top surface and a bottom surface opposite to the top surface, and included a non III-V group material. The pillar bases are disposed adjacent to the top surface of the substrate structure. The light emitting device includes a III-V group material, and comprises a plurality of electrode pads. The electrically connective materials are interposed between the electrode pads of the light emitting device and the pillar bases.

### CROSS-REFERENCE TO RELATED APPLICATIONS

This application claims the benefit of and priority to U.S. Provisional Application No. 62/681,533, filed Jun. 6, 2018, the contents of which are incorporated herein by reference in their entirety.

### BACKGROUND

### 1. Field of the Disclosure

The present disclosure relates to an electronic apparatus and a manufacturing method, and to an electronic apparatus including at least one light emitting device, and a method for manufacturing the same.

### 2. Description of the Related Art

Along with the rapid development in electronics industry and the progress of semiconductor processing technologies, electronic apparatuses are integrated with an increasing number of electronic devices to achieve better electrical performance and more functions. Accordingly, the electronic apparatuses are provided with more input/output (I/O) connections. To manufacture electronic apparatuses with an increased number of I/O connections, sizes of the electronic apparatuses may correspondingly increase. Thus, a manufacturing cost may correspondingly increase. Alternatively, or additionally, to minimize sizes of electronic apparatuses with an increased number of I/O connections, a pillar density of a substrate used for carrying the electronic devices may correspondingly increase. Thus, a diameter of the pillar may decrease. As a result, an intermetallic compound (IMC) occurred during a reflow process is an issue, and a yield of the electronic apparatus may be reduced.

### SUMMARY

In some embodiments, an electronic apparatus includes a substrate structure, a plurality of pillar bases, at least one light emitting device and a plurality of electrically connective materials. The substrate structure has a top surface and a bottom surface opposite to the top surface, and includes a non III-V group material. The pillar bases are disposed adjacent to the top surface of the substrate structure. The light emitting device includes a III-V group material, and comprises a plurality of electrode pads. The electrically connective materials are interposed between the electrode pads of the light emitting device and the pillar bases.

In some embodiments, an electronic apparatus includes a substrate structure, a plurality of pillar bases, at least one light emitting device and a plurality of electrically connective materials. The substrate structure has a top surface and a bottom surface opposite to the top surface, and includes a silicon material. The pillar bases are disposed adjacent to the top surface of the substrate structure. Each of the pillar bases includes a first conductive layer disposed adjacent to the top surface of the substrate structure, a barrier layer disposed on the first conductive layer, and a second conductive layer disposed on the barrier. The light emitting device comprises a plurality of electrode pads. The electrically connective materials connect the electrode pads of the light emitting device and the pillar bases.

In some embodiments, a method for manufacturing an electronic apparatus includes: (a) providing a substrate structure having a top surface and a bottom surface opposite to the top surface; (b) forming a plurality of pillar structures adjacent to the top surface of the substrate structure, wherein each of the pillar structures includes a pillar base and a soldering material, the pillar base includes a first conductive layer disposed adjacent to the top surface of the substrate structure, a barrier layer disposed on the first conductive layer, and a second conductive layer disposed on the barrier, and the soldering material is disposed on the second conductive layer; (c) providing at least one electronic device including a plurality of electrode pads; (d) attaching the at least one electronic device to the substrate structure, wherein the electrode pads of the at least one electronic device contact the soldering materials of the pillar structures; and (e) conducting a reflow process so that the electrode pads of the at least one electronic device and the soldering materials of the pillar structures are bonded together to form a plurality of electrically connective materials.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a top view of a substrate panel according to some embodiments of the present disclosure.

FIG. 2 illustrates an enlarged view of a substrate structure according to some embodiments of the present disclosure.

FIG. 3 illustrates a cross-sectional view of the substrate structure taken along line 3-3 of FIG. 2.

FIG. 4 illustrates an enlarged view of a portion of the substrate structure of FIG. 3.

FIG. 5 illustrates a cross-sectional view of the substrate structure taken along line 5-5 of FIG. 2.

FIG. 6 illustrates a cross-sectional view of the substrate structure taken along line 6-6 of FIG. 2.

FIG. 7 illustrates a cross-sectional view of a substrate structure according to some embodiments of the present disclosure.

FIG. 8 illustrates a cross-sectional view of a substrate structure according to some embodiments of the present disclosure.

FIG. 9 illustrates a top view of a substrate structure according to some embodiments of the present disclosure.

FIG. 10 illustrates a cross-sectional view of the substrate structure taken along line 10-10 of FIG. 9.

FIG. 11 illustrates an enlarged view of a portion of the substrate structure of FIG. 10.

FIG. 12 illustrates a bottom view of an electronic device assembly according to some embodiments of the present disclosure.

FIG. 13 illustrates a cross-sectional view of the electronic device assembly taken along line 13-13 of FIG. 12.

FIG. 14 illustrates a cross-sectional view of an electronic apparatus according to some embodiments of the present disclosure.

FIG. 15 illustrates an enlarged view of a portion of the electronic apparatus of FIG. 14.

FIG. 16 illustrates a cross-sectional view of an enlarged portion of an electronic apparatus according to some embodiments of the present disclosure.

FIG. 17 illustrates a cross-sectional view of an electronic apparatus according to some embodiments of the present disclosure.

FIG. 18 illustrates a bottom view of an electronic device assembly according to some embodiments of the present disclosure.

FIG. 19 illustrates a cross-sectional view of the electronic device assembly taken along line 19-19 of FIG. 18.

FIG. 20 illustrates a cross-sectional view of an electronic apparatus according to some embodiments of the present disclosure.

FIG. 21 illustrates one or more stages of an example of a method for manufacturing an electronic apparatus according to some embodiments of the present disclosure.

FIG. 22 illustrates one or more stages of an example of a method for manufacturing an electronic apparatus according to some embodiments of the present disclosure.

FIG. 23 illustrates one or more stages of an example of a method for manufacturing an electronic apparatus according to some embodiments of the present disclosure.

FIG. 24 illustrates one or more stages of an example of a method for manufacturing an electronic apparatus according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In a comparative semiconductor flip-chip bonding method, a semiconductor die with a plurality of copper pillars is provided. Then, a plurality of solders are formed on a respective one of the pillars. Then, the semiconductor die is placed on a substrate, so that the solder on the copper pillar contacts the pad of the substrate. After a reflow process, the solder is melted to join to the pad so as to form a semiconductor flip-chip bonded device. During the reflow process, the solder may react with the pad of the substrate so as to form intermetallic compounds (IMCs). Typically, the material of the solder is a tin silver alloy (e.g., SnAg), the material of the pad is copper (Cu), and the material of an IMC is thus a combination of tin, silver and copper, such as Cu₆Sn₅ or Cu₃Sn₄. IMCs can make the bonding between the solder and the pad tighter. However, a relatively thicker IMC layer will reduce the shear strength of the semiconductor flip-chip bonded device because the IMCs are brittle. Moreover, if the semiconductor die is a micro device (e.g., a microlighting device), a diameter or width of the copper pillar is very small (e.g., less than 75 μm), and a size of the solder is very small. Thus, the volume ratio of the IMCs to the solder can be relatively large, which can result in joint crack. As a result, the yield of such semiconductor flip-chip bonded device may be further reduced.

To address the above concerns, at least some embodiments of the present disclosure provide for a substrate structure which includes a plurality of fine pitch pillars. In some embodiments, the substrate structure is bonded with at least one light emitting device to form an electronic apparatus. At least some embodiments of the present disclosure further provide for techniques for manufacturing the electronic apparatus.

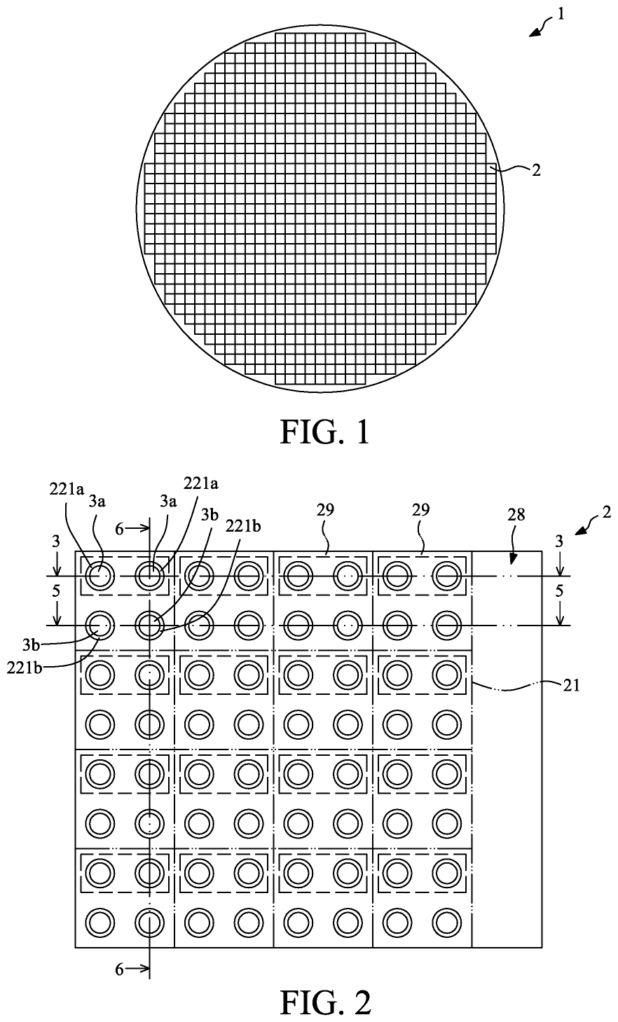

FIG. 1 illustrates a top view of a substrate panel 1 according to some embodiments of the present disclosure. The substrate panel 1 may be non-metal material, for example, a ceramic material, a glass material, a substrate or a semiconductor wafer. As shown in FIG. 1, the shape of the substrate panel 1 may be substantially circular or elliptical. However, in one or more embodiments, the shape of the substrate panel 1 may be substantially rectangular or square. The substrate panel 1 may include a plurality of substrate structures 2 and a plurality of pillar structures (for example, including a plurality of first pillar structures 3a (FIG. 2) and a plurality of second pillar structures 3b (FIG. 2)).

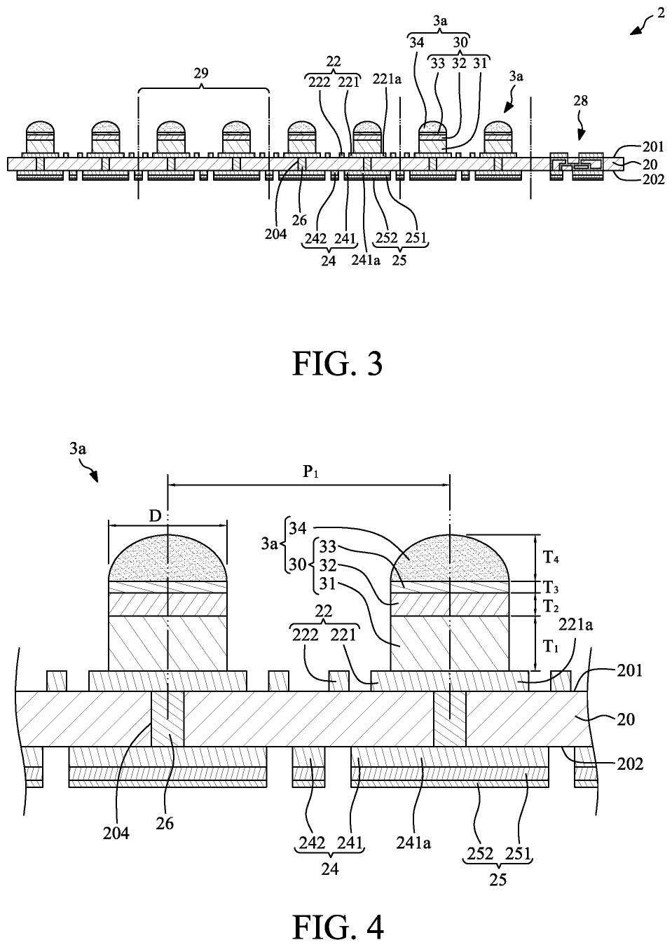

FIG. 2 illustrates an enlarged view of a substrate structure 2 according to some embodiments of the present disclosure. FIG. 3 illustrates a cross-sectional view of the substrate structure 2 taken along line 3-3 of FIG. 2. As shown in FIG. 2, the shape of the substrate structure 2 may be substantially rectangular or square. However, in one or more embodiments, the shape of the substrate structure 2 may be substantially circular or elliptical. As shown in FIG. 3, the substrate structure 2 may include a substrate body 20, a top circuit layer 22, a bottom circuit layer 24, a plurality of conductive vias 26 and at least one complementary metal-oxide-semiconductor (CMOS) controller 28.

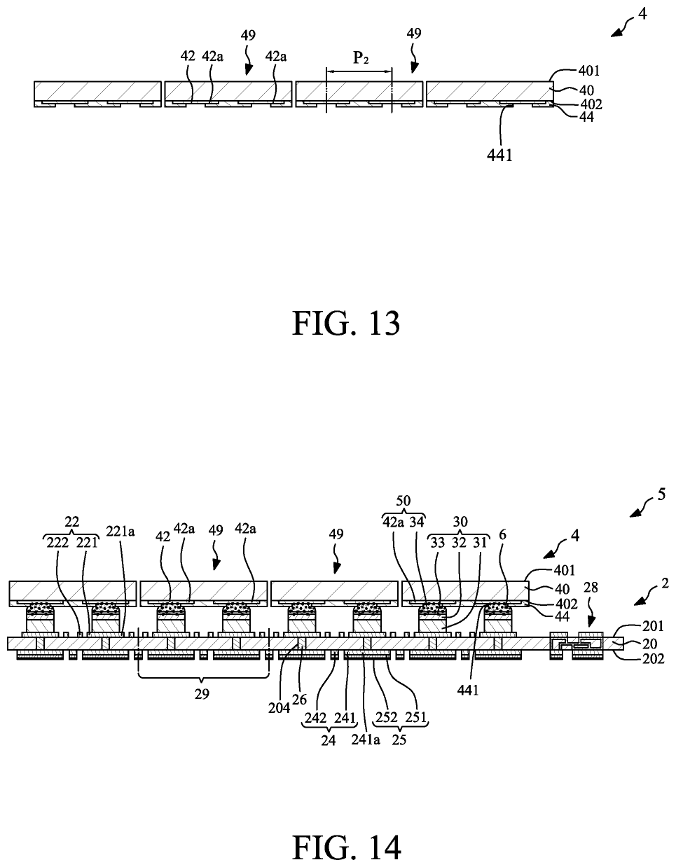

The material of the substrate body 20 of the substrate structure 2 may include a non III-V group material such as a glass-reinforced epoxy resin material, bismaleimide triazine (BT), epoxy, silicon, print circuit board (PCB) material, glass or ceramic. Alternatively, the substrate body 20 may include, or be formed from, a cured PID material such as epoxy or polyimide (PI) including photoinitiators. The substrate body 20 has a top surface 201 and a bottom surface 202 opposite to the top surface 201, and defines a plurality of through holes 204 extending from the top surface 201 to the bottom surface 202. As shown in FIG. 3, a top surface of the substrate structure 2 may be the top surface 201 of the substrate body 20 or a top surface of the top circuit layer 22. Further, a bottom surface of the substrate structure 2 may be the bottom surface 202 of the substrate body 20 or a bottom surface of the bottom circuit layer 24. The bottom surface of the substrate structure 2 is opposite to the top surface of the substrate structure 2. As shown in FIG. 2, the substrate body 20 of the substrate structure 2 may include a plurality of substrate unit areas 29 arranged in an array. The substrate unit areas 29 are defined by a plurality of imaginary lines 21 cross with each other. Each of the substrate unit areas 29 may correspond to an electronic device 49 (FIG. 12 and FIG. 13). For example, there are 4*4=16 substrate unit areas 29 in the substrate body 20, and the size of the substrate unit area 29 may be 200 micrometers (μm)*200 μm some embodiments, there may be 3*3=9, 5*5=25, or 7*7=49 substrate unit areas 29 in the substrate body 20. In addition, there may be at least two pillar structures (for example, at least one first pillar structures 3a and at least one second pillar structures 3b) disposed within a substrate unit area 29. As shown in FIG. 2, there are four pillar structures (for example, including two first pillar structures 3a and two second pillar structures 3b) disposed within a substrate unit area 29.

The conductive vias 26 extend through the substrate body 20. For example, during a manufacturing process, a conductive material (e.g., copper) may be disposed or formed in the through holes 204 of the substrate body 20 to form the conductive vias 26. Two ends of the conductive via 26 may be exposed from the top surface 201 and the bottom surface 202 of the substrate body 20 respectively.

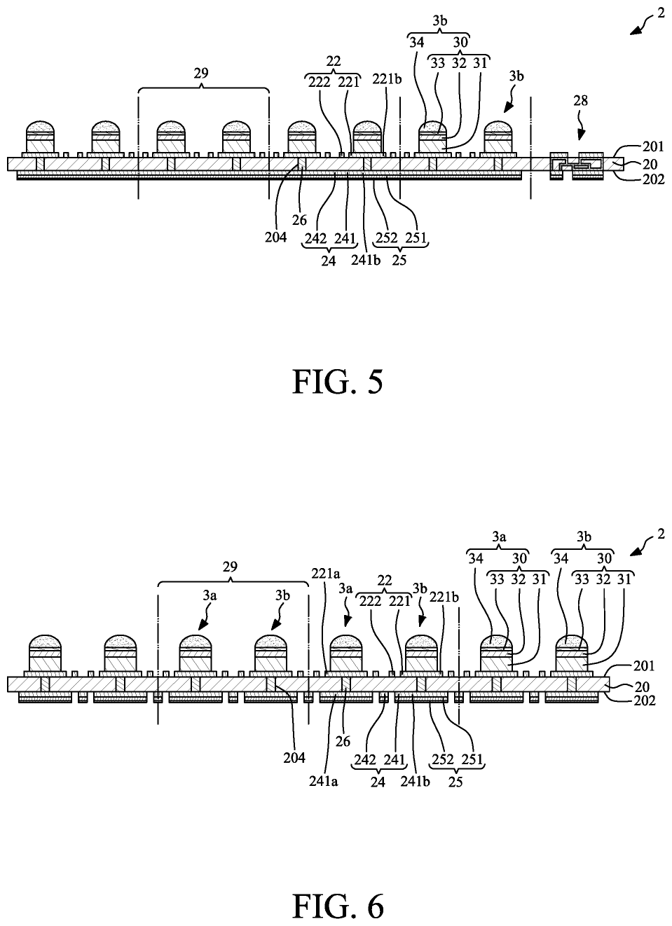

The top circuit layer 22 is disposed adjacent to the top surface 201 of the substrate body 20 or the top surface of the substrate structure 2. As shown in FIG. 3, the top circuit layer 22 is a redistribution layer (RDL) that is disposed on the top surface 201 of the substrate body 20, and includes a plurality of top traces 222 and a plurality of top pads 221 (for example, including a plurality of first top pads 221a and a plurality of second top pads 221b (FIG. 5)). The top pads 221 (for example, including the first top pads 221a and the second top pads 221b (FIG. 5)) cover and contact the top ends of the conductive vias 26. The material of the top circuit layer 22 may be copper (Cu), aluminum (Al), gold (Au), or an alloy thereof. In one or more embodiments, the top circuit layer 22 may be a patterned circuit layer, and a line width/line space (L/S) of the top circuit layer 22 may be equal to or less than about 3 μm/about 3 μm, equal to or less than about 2 μm/about 2 μm (such as, for example, about 1.8 μm/about 1.8 μm or less, about 1.6 μm/about 1.6 μm or less, or about 1.4 μm/about 1.4 μm or less), equal to or less than about 1 μm/about 1 μm, or equal to or less than about 0.5 μm/about 0.5 μm. It is noted that the top traces 222 of the top circuit layer 22 are not shown in FIG. 2.

The bottom circuit layer 24 is disposed adjacent to the bottom surface 202 of the substrate body 20 or the bottom surface of the substrate structure 2. As shown in FIG. 3, the bottom circuit layer 24 is a redistribution layer (RDL) that is disposed on the bottom surface 202 of the substrate body 20, and includes a plurality of bottom traces 242 and a plurality of bottom pads 241 (for example, including a plurality of first bottom pads 241a and a plurality of second bottom pads 241b (FIG. 5)). The bottom pads 241 (for example, including the first bottom pads 241a and the second bottom pads 241b (FIG. 5)) cover and contact the bottom ends of the conductive vias 26. The material of the bottom circuit layer 24 may be copper, aluminum, gold, or an alloy thereof. The conductive vias 26 are electrically connected to the top pads 221 (for example, including the first top pads 221a and the second top pads 221b (FIG. 5)) and the bottom pads 241 (for example, including the first bottom pads 241a and the second bottom pads 241b (FIG. 5)). In one or more embodiments, the bottom circuit layer 24 may be a patterned circuit layer, and the line width/line space (L/S) of the top circuit layer 22 is less than a line width/line space (L/S) of the bottom circuit layer 24. For example, the line width/line space (L/S) of the bottom circuit layer 24 may be equal to or greater than about 2 μm/about 2 μm, equal to or greater than about 5 μm/about 5 μm, or equal to or greater than about 7 μm/about 7 μm. In one or more embodiments, as shown in FIG. 2, there may be at least one first top pad 221a and at least one second top pad 221b disposed within a substrate unit area 29. For example, there are two first top pads 221a and two second top pads 221b disposed within a substrate unit area 29. In addition, there may be at least one first bottom pad 241a and at least one second bottom pad 241b disposed within a substrate unit area 29. For example, there are two first bottom pads 241a and two second bottom pads 241b disposed within a substrate unit area 29. In one or more embodiments, there may be a surface finish layer 25 disposed on the bottom circuit layer 24. For example, the surface finish layer 25 may include a nickel layer 251 and a gold layer 252. The thickness of the nickel layer 251 may be 3 μm, and the thickness of the gold layer 252 may be 0.2 μm.

The complementary metal-oxide-semiconductor (CMOS) controller 28 is disposed in the substrate body 20 of the substrate structure 2 and outside the substrate unit areas 29. The complementary metal-oxide-semiconductor (CMOS) controller 28 is electrically connects the top circuit layer 22, the bottom circuit layer 24 and the pillar structures (for example, including the first pillar structures 3a and the second pillar structures 3b). In one or more embodiments, each of the first top pads 221a is electrically connected to a complementary metal-oxide-semiconductor (CMOS) controller 28, thus, a number of the first top pads 221a is equal to a number of the complementary metal-oxide-semiconductor (CMOS) controller 28. Alternatively, each of the first bottom pads 241a is electrically connected to a complementary metal-oxide-semiconductor (CMOS) controller 28, thus, a number of the first bottom pads 241a is equal to a number of the complementary metal-oxide-semiconductor (CMOS) controller 28. In one or more embodiments, the second top pads 221b may be electrically connected to each other. Alternatively, the second bottom pads 241b may be electrically connected to each other (FIG. 5).

The pillar structures (for example, including a plurality of first pillar structures 3a and a plurality of second pillar structures 3b) are disposed adjacent to the top surface 201 of the substrate body 20 or the top surface of the substrate structure 2. As shown in FIG. 2, there are two first pillar structures 3a and two second pillar structures 3b disposed within a substrate unit area 29. Each of the first pillar structures 3a is disposed on each of the first top pads 221a directly, and each of the second pillar structures 3b is disposed on each of the second top pads 221b (FIG. 5) directly. As shown in FIG. 3, the first pillar structure 3a includes a pillar base 30 and a soldering material 34. The pillar base 30 is disposed on and contacts the first top pad 221a, and the soldering material 34 is disposed on the pillar base 30. The pillar base 30 stands on the first top pad 221a of the substrate body 20 or on the top surface 201 of the substrate body 20. Thus, the pillar base 30 is disposed adjacent to the top surface of the substrate structure 2. The pillar base 30 includes a first conductive layer 31, a barrier layer 32 and a second conductive layer 33. The first conductive layer 31 is disposed on and contacts the first top pad 221a, the barrier layer 32 is disposed on the first conductive layer 31, the second conductive layer 33 is disposed on the barrier layer 32, and the soldering material 34 is disposed on the second conductive layer 33. Thus, the first conductive layer 31 is disposed adjacent to the top surface of the substrate structure 2. For example, a material of the first conductive layer 31 includes copper, a material of the barrier layer 32 includes nickel (Ni), a material of the second conductive layer 33 includes copper, and a material of the soldering material 34 includes tin-silver (SnAg) alloy. The material of the first conductive layer 31 may be same as or different from the material of the second conductive layer 33. The barrier layer 32 can prevent the first conductive layer 31 from interacting with the second conductive layer 33 during a reflow process so as to reduce a formation of IMCs. The second conductive layer 33 can be a raw material of formation of IMCs during a reflow process. The soldering material 34 may be a flowable conductive material, and can react with an electrode pad 42 of an electronic device 49 (FIG. 13). The first conductive layer 31, the barrier layer 32, the second conductive layer 33 and the soldering material 34 may be formed by depositing such as sputtering or plating.

FIG. 4 illustrates an enlarged view of a portion of the substrate structure 2 of FIG. 3. The pillar base 30 may be a cylinder, and the soldering material 34 may be a hemisphere. A pitch P₁ between the pillar structures (e.g., the first pillar structures 3a) is equal to or less than about 75 μm, or equal to or less than about 40 μm. That is, a pitch P₁ between the pillar bases 30 is equal to or less than about 75 μm, or equal to or less than about 40 μm. In addition, a diameter D of the pillar structure (e.g., the first pillar structure 3a) is equal to or less than 40 μm, or equal to or less than 25 μm. In some embodiments, the diameter D of the pillar structure (e.g., the first pillar structure 3a) may be in a range of 20 μm to 25 μm. That is, a diameter D of the pillar base 30 from a top view is equal to or less than 40 μm, or equal to or less than 25 μm. In some embodiments, the diameter D of the pillar base 30 from a top view may be in a range of 20 μm to 25 μm. As shown in FIG. 4, a thickness T₁ of the first conductive layer 31 is greater than a thickness T₂ of the barrier layer 32, the thickness T₂ of the barrier layer 32 is greater than a thickness T₃ of the second conductive layer 33, and the thickness T₁ of the first conductive layer 31 is greater than the thickness T₃ of the second conductive layer 33. In addition, the thickness T₁ of the first conductive layer 31 is substantially equal to a thickness T₄ of the soldering material 34. For example, the thickness T₁ of the first conductive layer 31 may be about 15 μm, the thickness T₂ of the barrier layer 32 may be about 3 μm, the thickness T₃ of the second conductive layer 33 may be about 2 μm, and the thickness T₄ of the soldering material 34 may be about 16 μm.

FIG. 5 illustrates a cross-sectional view of the substrate structure 2 taken along line 5-5 of FIG. 2. As shown in FIG. 5, each of the second pillar structures 3b is disposed on each of the second top pads 221b, and the second bottom pads 241b are electrically connected to each other. The second pillar structure 3b includes the first conductive layer 31, the barrier layer 32, the second conductive layer 33 and the soldering material 34. The first conductive layer 31, the barrier layer 32, the second conductive layer 33 and the soldering material 34 of the second pillar structure 3b may be substantially same as or different from the first conductive layer 31, the barrier layer 32, the second conductive layer 33 and the soldering material 34 of the first pillar structure 3a, respectively. In addition, a pitch between the second pillar structures 3b is substantially equal or unequal to the pitch P₁ between the first pillar structures 3a, and a diameter of the second pillar structure 3b is substantially equal or unequal to the diameter D of the first pillar structure 3a.

FIG. 6 illustrates a cross-sectional view of the substrate structure 2 taken along line 6-6 of FIG. 2. As shown in FIG. 6, a total height (e.g., a sum of the thickness T₁ of the first conductive layer 31, a thickness T₂ of the barrier layer 32, a thickness T₃ of the second conductive layer 33, and the thickness T₄ of the soldering material 34) of the first pillar structure 3a may be substantially equal to a total height of the second pillar structure 3b. However, in other embodiment, the total height of the first pillar structure 3a may be greater than or less than the total height of the second pillar structure 3b. In addition, a pitch between the first pillar structure 3a and the second pillar structure 3b may be substantially equal to the pitch P₁ between the first pillar structures 3a.

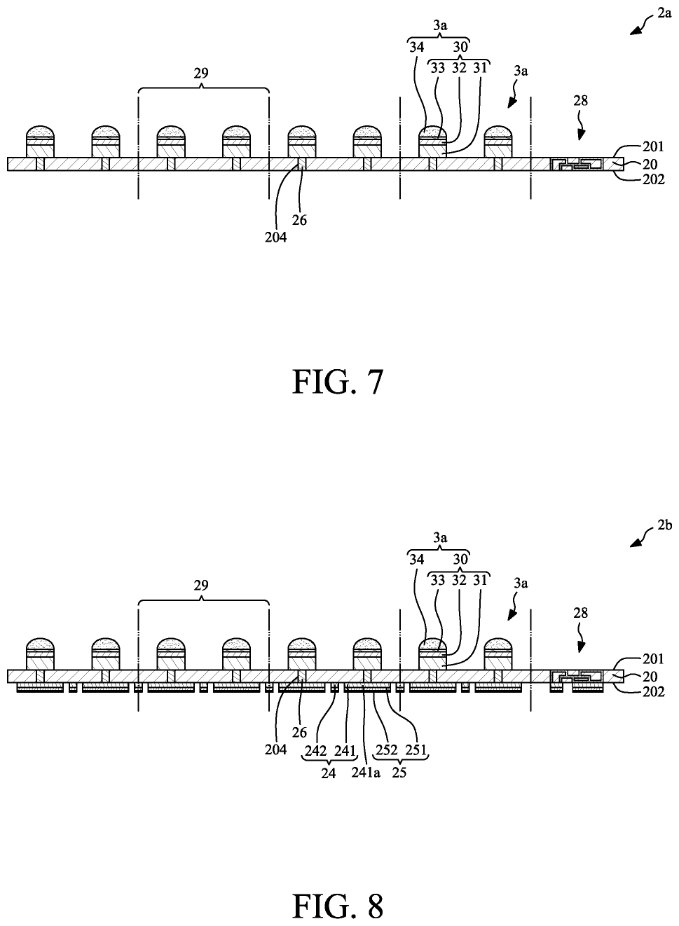

FIG. 7 illustrates a cross-sectional view of a substrate structure 2a according to some embodiments of the present disclosure. The substrate structure 2a of FIG. 7 may be similar to the substrate structure 2 of FIG. 1 through FIG. 6 except that the top circuit layer 22, the bottom circuit layer 24 and the surface finish layer 25 are omitted. Thus, the pillar structures (for example, including the first pillar structures 3a and the second pillar structures 3b) contact the conductive vias 26 directly, and the bottom ends of the conductive vias 26 are exposed from the second surface 202 of the substrate body 20.

FIG. 8 illustrates a cross-sectional view of a substrate structure 2b according to some embodiments of the present disclosure. The substrate structure 2b of FIG. 8 may be similar to the substrate structure 2 of FIG. 1 through FIG. 6 except that the top circuit layer 22 is omitted. Thus, the pillar structures (for example, including the first pillar structures 3a and the second pillar structures 3b) contact the conductive vias 26 directly.

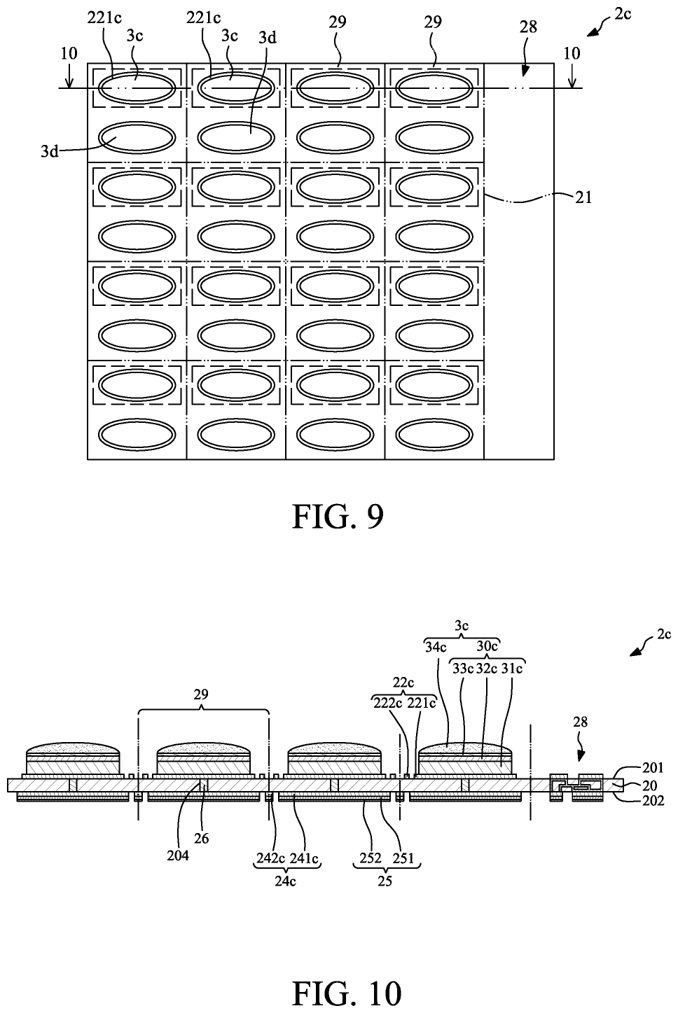

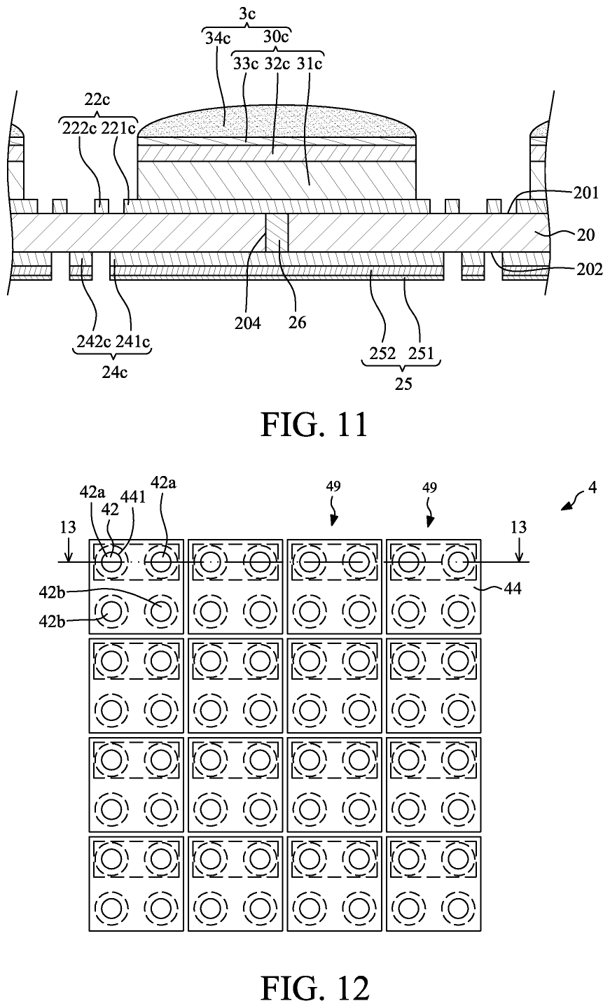

FIG. 9 illustrates a top view of a substrate structure 2c according to some embodiments of the present disclosure. FIG. 10 illustrates a cross-sectional view of the substrate structure 2c taken along line 10-10 of FIG. 9. FIG. 11 illustrates an enlarged view of a portion of the substrate structure 2c of FIG. 10. The substrate structure 2c of FIG. 9 and FIG. 10 may be similar to the substrate structure 2 of FIG. 1 through FIG. 6 except for the structures of the pillar structures (for example, including the third pillar structures 3c and the fourth pillar structures 3d). As shown in FIG. 9, the top view of the pillar structure (for example, the third pillar structure 3c or the fourth pillar structure 3d) is substantially elliptical rather than substantially circular. For example, the maximum width of the third pillar structure 3c is substantially equal to the maximum distance between the two sidewalls of the two first pillar structures 3a of FIG. 2. Furthermore, as shown in FIG. 10, the third pillar structure 3c includes a pillar base 30c and a soldering material 34c that are substantially equal to the pillar base 30 and the soldering material 34 of the first pillar structure 3a of FIG. 3, respectively. The pillar base 30c of the third pillar structure 3c includes a first conductive layer 31c, a barrier layer 32c and a second conductive layer 33c that are substantially equal to the first conductive layer 31, the barrier layer 32 and the second conductive layer 33 of the pillar base 30 of FIG. 3, respectively. As shown in FIG. 9, there are two pillar structures (for example, including a third pillar structure 3c and a fourth pillar structures 3d) disposed within a substrate unit area 29.

In addition, as shown in FIG. 10 and FIG. 11, the substrate structure 2c includes a top circuit layer 22c and a bottom circuit layer 24c. The top circuit layer 22c is disposed on the top surface 201 of the substrate body 20, and includes a plurality of top traces 222c and a plurality of first top pads 221c. The first top pads 221c cover and contact the top ends of the conductive vias 26. The bottom circuit layer 24c is disposed on the bottom surface 202 of the substrate body 20, and includes a plurality of bottom traces 242c and a plurality of first bottom pads 241c. The first bottom pads 241c cover and contact the bottom ends of the conductive vias 26. The line width/line space (L/S) of the top circuit layer 22c is less than a line width/line space (L/S) of the bottom circuit layer 24c. As shown in FIG. 9, the top view of the top pads (for example, the first top pads 221c) is substantially elliptical rather than substantially circular.

FIG. 12 illustrates a bottom view of an electronic device assembly 4 according to some embodiments of the present disclosure. FIG. 13 illustrates a cross-sectional view of the electronic device assembly 4 taken along line 13-13 of FIG. 12. The electronic device assembly 4 includes a plurality of electronic devices 49 arranged in an array. For example, there are 4*4=16 electronic devices 49 in the electronic device assembly 4. In some embodiments, there may be 3*3=9, 5*5=25, or 7*7=49 electronic devices 49 in the electronic device assembly 4. As shown in FIG. 12, the shape of the electronic device assembly 4 may be substantially rectangular or square. However, in one or more embodiments, the shape of the electronic device assembly 4 may be substantially circular or elliptical. The electronic device 49 may be a light emitting device such as a light emitting diode (LED). Alternatively, the electronic device 49 may be a microlighting device such as a micro LED. A gap between adjacent two electronic devices 49 may be less than 200 μm.

The electronic device 49 may include a device body 40, a plurality of electrode pads 42 (for example, including a plurality of first electrode pads 42a and a plurality of second electrode pads 42b) and a protection layer 44. The material of the device body 40 may include a transparent and light emitting material. In some embodiments, the material of the device body 40 may include a III-V group material which is a combination of group III elements and group V elements. For example, the material of the device body 40 may include GaN, GaAs, InP, InGaAs, InGaP, InAlGaAs or InGaAsP. The device body 40 has a top surface 401 and a bottom surface 402 opposite to the top surface 401. The size of the electronic device 49 may be 200 μm*200 μm, and a size of each of the electronic devices 49 may correspond to a size of each of the substrate unit areas 29 of the substrate structure 2 of FIG. 2 and FIG. 3. The electronic device 49 may include at least two electrode pads 42. That is, there may be at least two electrode pads 42 disposed within an electronic device 49. As shown in FIG. 12, there are four electrode pads 42 (for example, including two first electrode pads 42a and two second electrode pads 42b) disposed within an electronic device 49.

The electrode pads 42 (for example, including the first electrode pads 42a and the second electrode pads 42b) are disposed adjacent to the bottom surface 402 of the device body 40. As shown in FIG. 13, the electrode pads 42 (for example, including the first electrode pads 42a and the second electrode pads 42b) are disposed on the bottom surface 402 of the device body 40. Thus, the electrode pads 42 (for example, including the first electrode pads 42a and the second electrode pads 42b) contact the device body 40. In some embodiments, the electrode pads (for example, including the first electrode pads 42a and the second electrode pads 42b) are joined to the device body 40 by soldering. The material of the electrode pads 42 may be copper or gold. For example, the first electrode pad 42a is a P-type electrode pad, and the second electrode pad 42b is an N-type electrode pad. The thickness of the electrode pad 42 may be related to the thickness T₃ of the second conductive layer 33 (FIG. 4). The thickness T₃ of the second conductive layer 33 (FIG. 4) may be equal to or greater than the thickness of the electrode pad 42. For example, the thickness T₃ of the second conductive layer 33 (FIG. 4) may be greater than the thickness of the electrode pad 42 by five to ten times. In one embodiment, the thickness of the electrode pad 42 may be 0.1 μm to 0.2 μm. As shown in FIG. 13, a pitch P₂ between the electrode pads 42 (for example, including the first electrode pads 42a and the second electrode pads 42b) is equal to or less than 75 or equal to or less than 40 μm. It is noted that the pitch P₂ between the electrode pads 42 is substantially equal to the pitch P₁ between the pillar structures (e.g., the first pillar structures 3a) of FIG. 4.

The protection layer 44 is disposed adjacent to the bottom surface 402 of the device body 40. As shown in FIG. 13, the protection layer 44 is disposed on the bottom surface 402 of the device body 40 to cover a portion of each of the electrode pads 42. In addition, the protection layer 44 defines a plurality of openings 441 to expose portions of the electrode pads 42. A material of the protection layer 44 may include a solder resist material, such as, for example, benzocyclobutene (BCB) or polyimide.

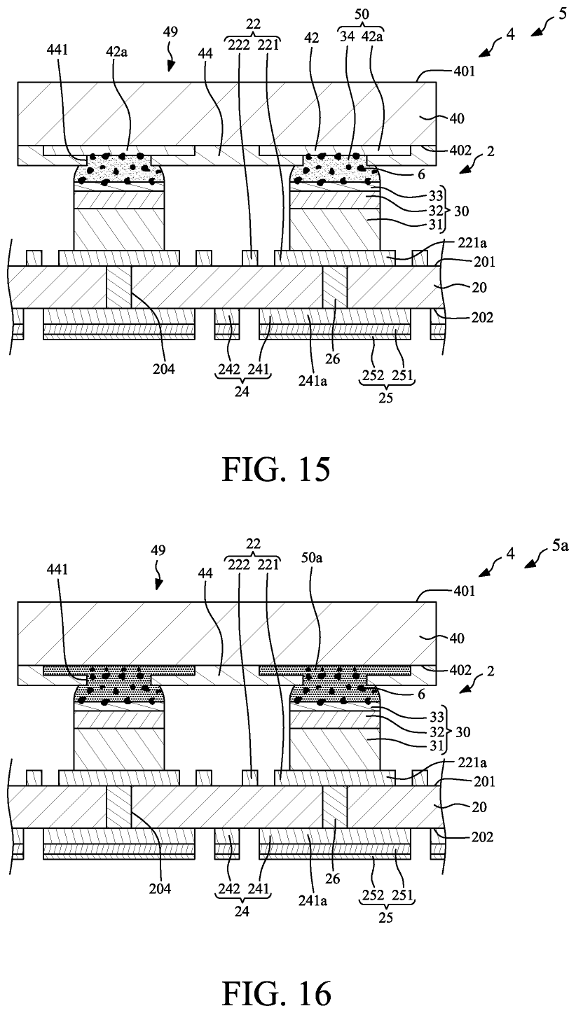

FIG. 14 illustrates a cross-sectional view of an electronic apparatus 5 according to some embodiments of the present disclosure. FIG. 15 illustrates an enlarged view of a portion of the electronic apparatus 5 of FIG. 14. The electronic apparatus 5 includes a substrate structure 2, a plurality of pillar bases (including, for example, the pillar bases 30 of the first pillar structure 3a and the pillar bases 30 of the second pillar structure 3b), an electronic device assembly 4 and a plurality of electrically connective materials 50 (e.g., bonding joint structures). The substrate structure 2 and the pillar bases (including, for example, the pillar bases 30 of the first pillar structure 3a and the pillar bases 30 of the second pillar structure 3b) of FIG. 14 and FIG. 15 are substantially the same as the substrate structure 2 and the pillar bases (including, for example, the pillar bases 30 of the first pillar structure 3a and the pillar bases 30 of the second pillar structure 3b) of FIG. 1 through FIG. 6. The electronic device assembly 4 is substantially the same as the electronic device assembly 4 of FIG. 12 and FIG. 13. The electronic device assembly 4 is attached to the substrate structure 2, and the second surface 402 of the device body 40 of the electronic device 49 faces the first surface 201 of the substrate body 20 of the substrate structure 2. The electronic device 49 of the electronic device assembly 4 is electrically connected to the substrate structure 2 through the electrode pads 42 (for example, including the first electrode pads 42a and the second electrode pads 42b) and the pillar structures (for example, including the first pillar structures 3a and the second pillar structures 3b). In some embodiments, at least two electrode pads 42 (for example, including the first electrode pads 42a and the second electrode pads 42b) within the electronic device 49 of the electronic device assembly 4 are electrically connected to at least two pillar structures (for example, including the first pillar structures 3a and the second pillar structures 3b) in the substrate unit area 29 of the substrate structure 2. Further, at least one first electrode pad 42a contacts at least one first pillar structure 3a, and at least one second electrode pad 42b contacts at least one second pillar structure 3b. As shown in FIG. 14 and FIG. 15, each of the first electrode pads 42a contacts each of the first pillar structures 3a, and each of the second electrode pads 42b contacts each of the second pillar structures 3b. The first electrode pad 42a contacts the soldering material 34 of the first pillar structure 3a. After a reflow process conducted under, for example, 250° C., the soldering material 34 may be melted to fill the openings 441 of the protection layer 44. Meanwhile, the soldering materials 34, the electrode pads 42 (e.g., the first electrode pads 42a) may react with each other to form at least one intermetallic compound (IMC) 6. Thus, the soldering materials 34 and the electrode pads 42 (e.g., the first electrode pad 42a) are bonded and jointed together to form the electrically connective materials 50. That is, the electrically connective materials 50 are formed from the soldering materials 34 and the electrode pads 42 (e.g., the first electrode pad 42a). The electrically connective materials 50 are interposed between the light emitting device 49 and the pillar bases 30 so as to connect the light emitting device 49 and the pillar bases 30. In some embodiments, the electrically connective materials 50 may be interposed between the bottom surface 402 of the device body 40 of the electronic device 49 and the second conductive layers 33 of the pillar bases 30 so as to connect the bottom surface 402 of the device body 40 of the electronic device 49 and the second conductive layers 33 of the pillar bases 30. In some embodiments, the electrically connective materials 50 may further extend to and contact the periphery surfaces of the pillar bases 30.

The IMC 6 may be a plurality of particles that are dispersed in the electrically connective materials 50. In some embodiments. The IMC 6 may be disposed in the first electrode pad 42a, an interface between the first electrode pad 42a and the soldering material 34, the soldering material 34, and an interface between the soldering material 34 and the second conductive layer 33. The material of the IMC 6 includes any one or more of tin (Sn), silver (Ag), copper (Cu), nickel (Ni) and gold (Au). That is, the IMC 6 may be a Sn, Ag, Cu, Ni, Au combination. For example, the IMC 6 may include Cu₆Sn₅, Cu₃Sn, AuSn₄, (Au, Cu)₆Sn, Ni₆Sn₅, and Ni₃Sn₄.

In the embodiment illustrated in FIG. 14 and FIG. 15, the size of the electronic device 49 of the electronic device assembly 4 may be 200 μm*200 μm, and each of the electronic devices 49 may be controlled individually, thus, the resolution of the electronic apparatus 5 may be relative high. In addition, the barrier layer 32 can prevent too much IMC 6 occurred, so as to avoid the crack or break occurred in the electrically connective materials 50 due to the defect (e.g., neck defect) caused by too much IMC 6, especially when first electrode pads 42a and first pillar structures 3a are fine pitch (e.g., a pitch that is less than 75 μm). Therefore, the electrode pad 42a can be bonded to the first pillar structure 3a securely, and the yield rate of the electrically connective material 50 is improved. As a result, the electrical performance and reliability of electronic apparatus 5 is also improved.

FIG. 16 illustrates a cross-sectional view of an enlarged portion of an electronic apparatus 5a according to some embodiments of the present disclosure. The electronic apparatus 5a of FIG. 16 may be similar to the electronic apparatus 5 of FIG. 14 through FIG. 15 except for a structure of the electrically connective material 50a. As shown in FIG. 16, the electrically connective material 50a is a eutectic of the soldering material 34 (FIG. 15) and the electrode pad 42a (FIG. 15). That is, after a reflow process, the soldering material 34 (FIG. 15) and the electrode pad 42a (FIG. 15) are fused together to form a eutectic electrically connective material 50a. Thus, there is no boundary between the soldering material 34 (FIG. 15) and the electrode pad 42a (FIG. 15). In addition, the IMC 6 may be disposed in the electrically connective material 50a, and an interface between the electrically connective material 50a and the second conductive layer 33.

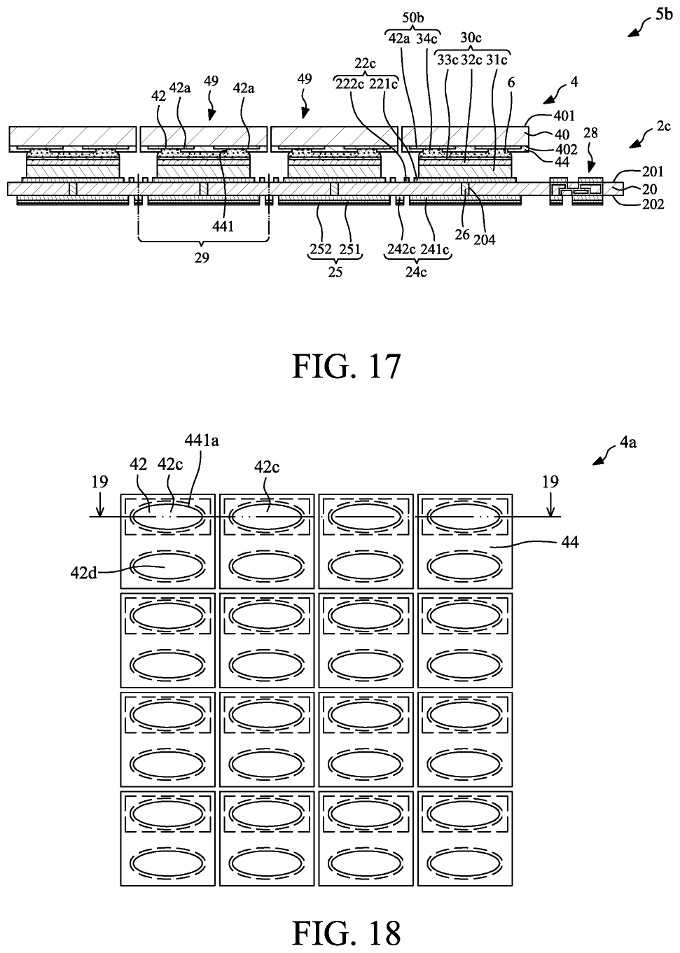

FIG. 17 illustrates a cross-sectional view of an electronic apparatus 5b according to some embodiments of the present disclosure. The electronic apparatus 5b of FIG. 17 may be similar to the electronic apparatus 5 of FIG. 14 through FIG. 15 except that the substrate structure 2 is replaced by the substrate structure 2c of FIG. 9 through FIG. 11. As shown in FIG. 17, two first electrode pads 42a is bonded and electrically connected to one third pillar structure 3c. That is, two first electrode pads 42a contact one third pillar structure 3c. Thus, the electrically connective material 50b may be formed from two first electrode pads 42a and one soldering material 34c of the third pillar structure 3c. Therefore, even one first electrode pad 42a does not contact the third pillar structure 3c, if the other first electrode pad 42a contacts the third pillar structure 3c, the bonding joint structure (e.g., the electrically connective material 50b) may still be qualified. Thus, the yield rate of the bonding joint structure (e.g., the electrically connective material 50b) of the electronic apparatus 5b is increased.

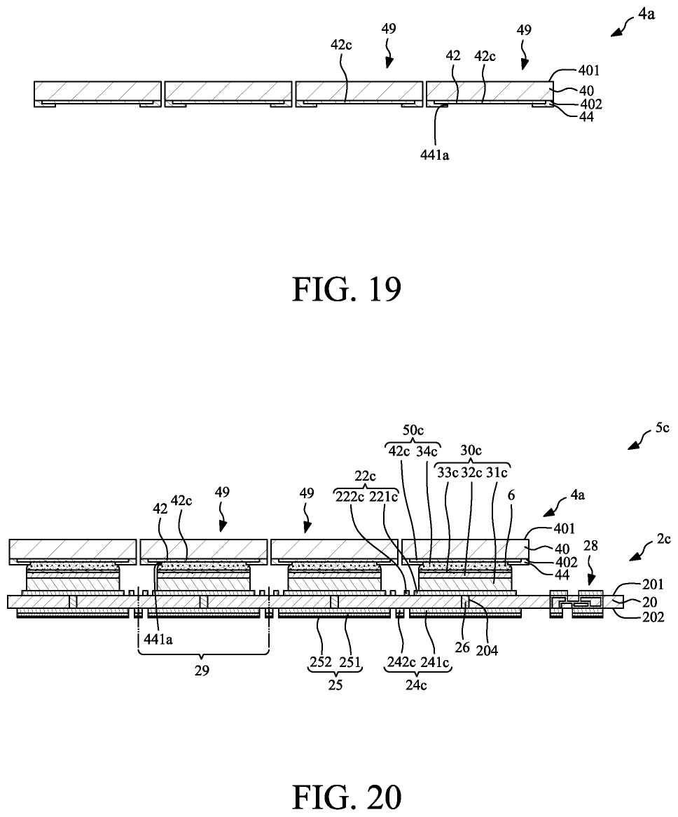

FIG. 18 illustrates a bottom view of an electronic device assembly 4a according to some embodiments of the present disclosure. FIG. 19 illustrates a cross-sectional view of the electronic device assembly 4a taken along line 19-19 of FIG. 18. The electronic device assembly 4a of FIG. 18 and FIG. 19 may be similar to the electronic device assembly 4 of FIG. 12 through FIG. 13 except for the structures of the electrode pads 42 (for example, including the third electrode pads 42c and the fourth electrode pads 42d). As shown in FIG. 18, the top view of the electrode pads 42 (for example, including the third electrode pads 42c and the fourth electrode pads 42d) is substantially elliptical rather than substantially circular. For example, the maximum width of the third electrode pad 42c is substantially equal to the maximum distance between the two sidewalls of the two first electrode pads 42a shown in FIG. 12 and FIG. 13. As shown in FIG. 18, there are two electrode pads 42 (for example, including a third electrode pad 42c and a fourth electrode pad 42d) disposed within an electronic device 49. As shown in FIG. 19, the protection layer 44 defines a plurality of openings 441a to expose portions of the electrode pads 42c.

FIG. 20 illustrates a cross-sectional view of an electronic apparatus 5c according to some embodiments of the present disclosure. The electronic apparatus 5c of FIG. 20 may be similar to the electronic apparatus 5b of FIG. 17 except that the electronic device assembly 4 is replaced by the electronic device assembly 4a of FIG. 18 and FIG. 19. As shown in FIG. 20, one third electrode pad 42c is bonded and electrically connected to one third pillar structure 3c to form an electrically connective material 50c. That is, the one third electrode pad 42c selectively or solely contacts the one third pillar structure 3c. Therefore, the bonding area between the third electrode pad 42c and the third pillar structure 3c is increased. The yield of the electrically connective material 50c is increased. Thus, the yield rate of the bonding joint structure (e.g., the electrically connective material 50c) of the electronic apparatus 5c is increased. In addition, it is noted that one fourth electrode pads 42d (FIG. 18) is bonded and electrically connected to one fourth pillar structure 3d (FIG. 9).

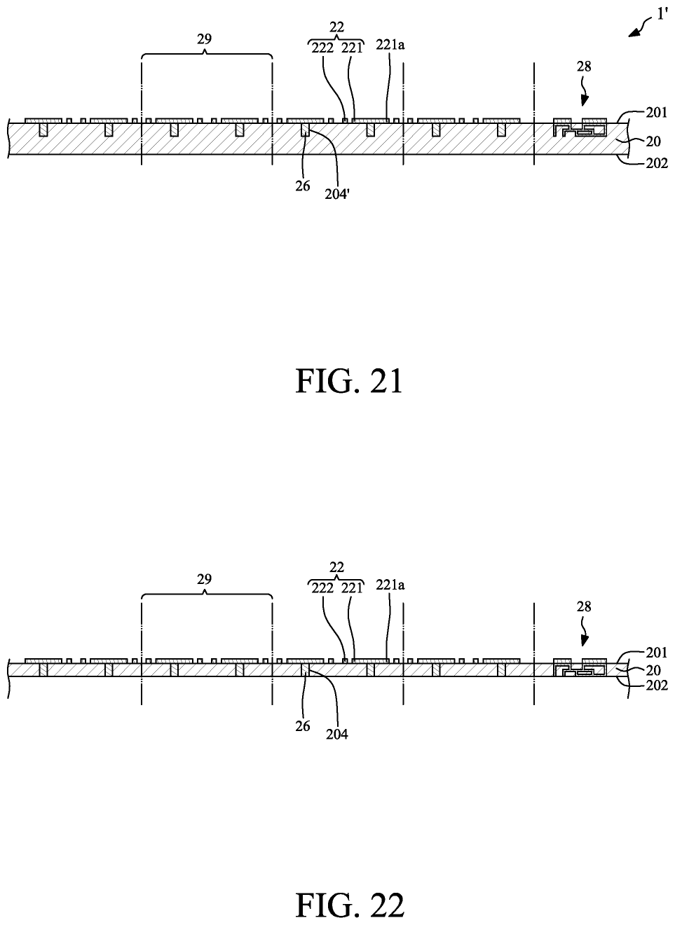

FIG. 21 through FIG. 24 illustrate a method for manufacturing an electronic apparatus according to some embodiments of the present disclosure. In some embodiments, the method is for manufacturing the electronic apparatus 5 shown in FIG. 14.

Referring to FIG. 21 through FIG. 23, a substrate structure 2 is provided. The substrate structure 2 is manufactured as follows. Referring to FIG. 21, a substrate 1′ is provided. The substrate 1′ may include a substrate body 20, a top circuit layer 22, a plurality of conductive vias 26 and at least one complementary metal-oxide-semiconductor (CMOS) controller 28. The material of the substrate body 20 may include a non III-V group material such as a glass-reinforced epoxy resin material, bismaleimide triazine (BT), epoxy, silicon, print circuit board (PCB) material, glass or ceramic. Alternatively, the substrate body 20 may include, or be formed from, a cured PID material such as epoxy or polyimide (PI) including photoinitiators. The substrate body 20 has a top surface 201 and a bottom surface 202 opposite to the top surface 201, and defines a plurality of blind holes 204′. The blind holes 204′ extend from the top surface 201 to the interior of the substrate body 20, and do not extend through the substrate body 20. The conductive vias 26 are disposed in the blind holes 204′. Thus, the conductive vias 26 do not extend through the substrate body 20. A top end of the conductive via 26 is selectively or solely exposed from the top surface 201 of the substrate body 20.

In addition, the substrate body 20 may include a plurality of substrate unit areas 29 arranged in an array. Each of the substrate unit areas 29 may correspond to an electronic device 49 (FIG. 12 and FIG. 13). The top circuit layer 22 is disposed adjacent to the top surface 201 of the substrate body 20. The top circuit layer 22 is a redistribution layer (RDL) that is disposed on the top surface 201 of the substrate body 20, and includes a plurality of top traces 222 and a plurality of top pads 221 (for example, including a plurality of first top pads 221a and a plurality of second top pads 221b (FIG. 5)). The top pads 221 (for example, including the first top pads 221a and the second top pads 221b (FIG. 5)) cover and contact the top ends of the conductive vias 26. In one or more embodiments, the top circuit layer 22 may be a patterned circuit layer, and a line width/line space (L/S) of the top circuit layer 22 may be equal to or less than about 3 μm/about 3 μm.

The complementary metal-oxide-semiconductor (CMOS) controller 28 is disposed in the substrate body 20 and outside the substrate unit areas 29. The complementary metal-oxide-semiconductor (CMOS) controller 28 is electrically connected to the top circuit layer 22. In one or more embodiments, each of the first top pads 221a is electrically connected to a complementary metal-oxide-semiconductor (CMOS) controller 28, thus, a number of the first top pads 221a is equal to a number of the complementary metal-oxide-semiconductor (CMOS) controller 28.

Referring to FIG. 22, the substrate body 20 is thinned from its bottom surface 202 by, for example, grinding. Thus, the blind holes 204′ become through holes 204 that extend through the substrate body 20, and the conductive vias 26 extend through the substrate body 20. The bottom end of the conductive via 26 is exposed from the bottom surface 202 of the substrate body 20.

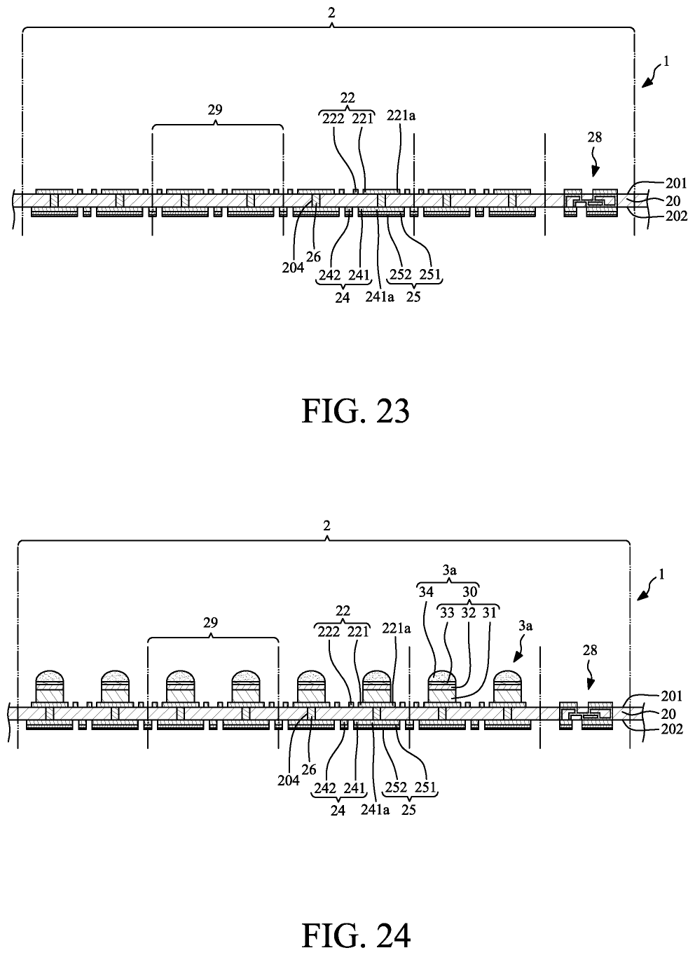

Referring to FIG. 23, a bottom circuit layer 24 is formed on the bottom surface 202 of the substrate body 20. The bottom circuit layer 24 is a redistribution layer (RDL) that includes a plurality of bottom traces 242 and a plurality of bottom pads 241 (for example, including a plurality of first bottom pads 241a and a plurality of second bottom pads 241b (FIG. 5)). The bottom pads 241 (for example, including the first bottom pads 241a and the second bottom pads 241b (FIG. 5)) cover and contact the bottom ends of the conductive vias 26. The conductive vias 26 are electrically connected to the top pads 221 (for example, including the first top pads 221a and the second top pads 221b (FIG. 5)) and the bottom pads 241 (for example, including the first bottom pads 241a and the second bottom pads 241b (FIG. 5)). In one or more embodiments, the bottom circuit layer 24 may be a patterned circuit layer, and the line width/line space (L/S) of the top circuit layer 22 is less than a line width/line space (L/S) of the bottom circuit layer 24. For example, the line width/line space (L/S) of the bottom circuit layer 24 may be equal to or greater than about 2 μm/about 2 μm. In one or more embodiments, there may be at least one first top pad 221a and at least one second top pad 221b disposed within a substrate unit area 29. For example, there may be two first bottom pads 241a and two second bottom pads 241b disposed within a substrate unit area 29. In one or more embodiments, a surface finish layer 25 may be formed or disposed on the bottom circuit layer 24. Meanwhile, a substrate panel 1 of FIG. 1 is obtained. The substrate panel 1 may include a plurality of substrate structures 2.

Referring to FIG. 24, a plurality of pillar structures (for example, including a plurality of first pillar structures 3a and a plurality of second pillar structures 3b (FIG. 5)) are formed or disposed adjacent to the top surface 201 of the substrate body 20 or the top surface of the substrate structure 2. Each of the first pillar structures 3a is formed or disposed on each of the first top pads 221a directly, and each of the second pillar structures 3b (FIG. 5) is formed or disposed on each of the second top pads 221b (FIG. 5) directly. As shown in FIG. 24, the first pillar structure 3a includes a pillar base 30 and a soldering material 34. The pillar base 30 is disposed on and contacts the first top pad 221a, and the soldering material 34 is disposed on the pillar base 30. The pillar base 30 stands on the first top pad 221a of the substrate body 20. The pillar base 30 includes a first conductive layer 31, a barrier layer 32 and a second conductive layer 33. The first conductive layer 31 is disposed on and contacts the first top pad 221a, the barrier layer 32 is disposed on the first conductive layer 31, the second conductive layer 33 is disposed on the barrier layer 32, and the soldering material 34 is disposed on the second conductive layer 33. For example, a material of the first conductive layer 31 includes copper, a material of the barrier layer 32 includes nickel (Ni), a material of the second conductive layer 33 includes copper, and a material of the soldering material 34 includes tin-silver (SnAg) alloy. The barrier layer 32 can prevent the first conductive layer 31 from interacting with the second conductive layer 33 during a reflow process so as to reduce a formation of IMCs. The second conductive layer 33 can be a raw material of formation of IMCs during a reflow process. The soldering material 34 can react with an electrode pad 42 of an electronic device 49 (FIG. 13). The first conductive layer 31, the barrier layer 32, the second conductive layer 33 and the soldering material 34 may be formed by depositing such as sputtering or plating.

Then, an electronic device assembly 4 (FIG. 12 and FIG. 13) is provided. The electronic device assembly 4 includes at least one electronic device 49. The electronic device 49 may be a light emitting device such as a light emitting diode (LED). Alternatively, the electronic device 49 may be a microlighting device such as a micro LED. The electronic device 49 may include a device body 40, a plurality of electrode pads 42 (for example, including a plurality of first electrode pads 42a and a plurality of second electrode pads 42b (FIG. 12)) and a protection layer 44. In some embodiments, the material of the device body 40 may include a III-V group material which is a combination of group III elements and group V elements. For example, the material of the device body 40 may include GaN, GaAs, InP, InGaAs, InGaP, InAlGaAs or InGaAsP. The device body 40 has a top surface 401 and a bottom surface 402 opposite to the top surface 401. The electrode pads 42 (for example, including the first electrode pads 42a and the second electrode pads 42b (FIG. 12)) are formed or disposed on the bottom surface 402 of the device body 40. The protection layer 44 is formed or disposed on the bottom surface 402 of the device body 40 to cover a portion of each of the electrode pads 42. In addition, the protection layer 44 defines a plurality of openings 441 to expose portions of the electrode pads 42.

It is noted that the pillar structures (e.g., the first pillar structures 3a) may be formed or disposed on the substrate structure 2 rather than on the electronic device 49 (e.g., light emitting device) because it is difficult to form a circuit layer or the pillar structures on the light emitting device 49 (e.g., light emitting device). In addition, the light emitting device 49 (e.g., light emitting device) is more expensive than the substrate structure 2, a yield loss of the light emitting device 49 (e.g., light emitting device) will increase the manufacturing cost hugely.

Then, the electronic device assembly 4 (including at least one electronic device 49) is attached to the substrate panel 1 (including the substrate structures 2), and the second surface 402 of the device body 40 of the electronic device 49 faces the first surface 201 of the substrate body 20 of the substrate structure 2. In some embodiments, at least two electrode pads 42 (for example, including the first electrode pads 42a and the second electrode pads 42b) within the electronic device 49 of the electronic device assembly 4 contact at least two pillar structures (for example, including the first pillar structures 3a and the second pillar structures 3b) in the substrate unit area 29 of the substrate structure 2. Further, at least one first electrode pad 42a contacts at least one first pillar structure 3a, and at least one second electrode pad 42b contacts at least one second pillar structure 3b. In some embodiments, each of the first electrode pads 42a contacts each of the first pillar structures 3a, and each of the second electrode pads 42b contacts each of the second pillar structures 3b. The first electrode pad 42a contacts the soldering material 34 of the first pillar structure 3a.

Then, a reflow process is conducted under, for example, 250° C., such that the soldering material 34 may be melted to fill the openings 441 of the protection layer 44. Meanwhile, the soldering materials 34 and the electrode pads 42 (e.g., the first electrode pads 42a) may react with each other to form at least one intermetallic compound (IMC) 6. Thus, the soldering materials 34 and the electrode pads 42 (e.g., the first electrode pad 42a) are bonded and jointed together to form a plurality of electrically connective materials 50 (FIG.14). In some embodiments, the electrically connective materials 50 may be interposed between the bottom surface 402 of the device body 40 of the electronic device 49 and the second conductive layers 33 of the pillar bases 30 so as to connect the bottom surface 402 of the device body 40 of the electronic device 49 and the second conductive layers 33 of the pillar bases 30.

In some embodiments. The IMC 6 may be disposed in the first electrode pad 42a, an interface between the first electrode pad 42a and the soldering material 34, the soldering material 34, and an interface between the soldering material 34 and the second conductive layer 33. In some embodiments, after the reflow process, the soldering materials 34 (FIG. 15) and the electrode pads 42a (FIG. 15) may be fused together to form a plurality of eutectic electrically connective materials 50a (FIG. 16).

Then, a singulation process is conducted to singulate the substrate panel 1 to form a plurality of electronic apparatuses 5 of FIG. 14.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic apparatus, comprising:
a substrate structure having a top surface and a bottom surface opposite to the top surface, and including a non III-V group material;
a plurality of pillar bases disposed adjacent to the top surface of the substrate structure;
at least one light emitting device including a III-V group material, wherein the light emitting device comprises a plurality of electrode pads; and
a plurality of electrically connective materials interposed between the electrode pads of the light emitting device and the pillar bases.

2. The electronic apparatus of claim 1, wherein the pillar bases are formed by depositing.

3. The electronic apparatus of claim 2, wherein the pillar bases are formed by plating.

4. The electronic apparatus of claim 1, wherein each of the pillar bases includes a first conductive layer disposed adjacent to the top surface of the substrate structure, a barrier layer disposed on the first conductive layer, and a second conductive layer disposed on the barrier; the electrically connective materials are interposed between the electrode pads of the light emitting device and the second conductive layers of the pillar bases.

5. The electronic apparatus of claim 1, wherein the light emitting device includes a device body and the electrode pads, the device body includes the III-V group material, and the electrode pads contact the device body.

6. The electronic apparatus of claim 5, wherein the electrode pads are joined to the device body.

7. The electronic apparatus of claim 6, wherein the electrode pads are joined to the device body by soldering.

8. The electronic apparatus of claim 1, wherein the electrically connective materials are formed from a flowable conductive material.

9. The electronic apparatus of claim 8, wherein the flowable conductive material includes a soldering material.

10. The electronic apparatus of claim 1, wherein the substrate structure comprises:
a substrate body having a top surface and a bottom surface opposite to the top surface, and including the non III-V group material;
a plurality of conductive vias extending through the substrate body;
a top circuit layer disposed adjacent to the top surface of the substrate body, and including a plurality of top pads, wherein the pillar bases are disposed on the top pads; and
a bottom circuit layer disposed adjacent to the bottom surface of the substrate body, and including a plurality of bottom pads, wherein the conductive vias are electrically connected to the top pads and the bottom pads.

11. The electronic apparatus of claim 10, wherein the top pads includes a plurality of first top pads and a plurality of second top pads, each of the first top pads is electrically connected to a complementary metal-oxide-semiconductor (CMOS) controller, and the second top pads are electrically connected to each other.

12. The electronic apparatus of claim 10, wherein the substrate body includes a plurality of substrate unit areas arranged in an array, the top pads includes a plurality of first top pads and a plurality of second top pads, and at least one first top pad and at least one second top pad are disposed in a substrate unit area.

13. The electronic apparatus of claim 1, wherein the substrate structure further comprises at least one complementary metal-oxide-semiconductor (CMOS) controller, and the pillar bases are electrically connected to the complementary metal-oxide-semiconductor (CMOS) controller.

14. An electronic apparatus, comprising:
a substrate structure having a top surface and a bottom surface opposite to the top surface, and including a silicon material;
a plurality of pillar bases disposed adjacent to the top surface of the substrate structure, wherein each of the pillar bases includes a first conductive layer disposed adjacent to the top surface of the substrate structure, a barrier layer disposed on the first conductive layer, and a second conductive layer disposed on the barrier;
at least one light emitting device comprising a plurality of electrode pads; and
a plurality of electrically connective materials connecting the electrode pads of the light emitting device and the pillar bases.

15. The electronic apparatus of claim 14, wherein each of the electrically connective materials is a eutectic of a soldering material and the electrode pad of the light emitting device.

16. The electronic apparatus of claim 14, wherein a material of the first conductive layer of the pillar base includes copper, a material of the barrier layer of the pillar base includes nickel, a material of the second conductive layer of the pillar base includes copper, and a material of the electrode pad includes copper or gold.

17. The electronic apparatus of claim 14, further comprising at least one intermetallic compound (IMC) dispersed in each of the electrically connective materials.

18. A method for manufacturing an electronic apparatus, comprising:
(a) providing a substrate structure having a top surface and a bottom surface opposite to the top surface;
(b) forming a plurality of pillar structures adjacent to the top surface of the substrate structure, wherein each of the pillar structures includes a pillar base and a soldering material, the pillar base includes a first conductive layer disposed adjacent to the top surface of the substrate structure, a barrier layer disposed on the first conductive layer, and a second conductive layer disposed on the barrier, and the soldering material is disposed on the second conductive layer;
(c) providing at least one electronic device including a plurality of electrode pads;
(d) attaching the at least one electronic device to the substrate structure, wherein the electrode pads of the at least one electronic device contact the soldering materials of the pillar structures; and
(e) conducting a reflow process so that the electrode pads of the at least one electronic device and the soldering materials of the pillar structures are bonded together to form a plurality of electrically connective materials.

19. The method of claim 18, wherein in (b), a material of the first conductive layer of the pillar base includes copper, a material of the barrier layer of the pillar base includes nickel, a material of the second conductive layer of the pillar base includes copper, a material of the soldering material includes tin-silver (SnAg) alloy; and in (c), a material of the electrode pads includes copper or gold.

20. The method of claim 18, wherein in (e), the soldering materials and the electrode pads are fused together to form a plurality of eutectic electrically connective materials.
